(19) United States
(12) Patent Application Publication
(10) Pub. No.: US 2014/0063762 A1
(43) Pub. Date: Mar. 6, 2014

(54) SILVER ALLOY WIRE FOR BONDING APPLICATIONS

(71) Applicant: Heraeus Materials Technology GmbH & Co. KG, Hanau (DE)

(72) Inventors: Jae-Sung RYU, Bucheon-si (KR); Eun-Kyun CHUNG, Nam-Ku (KR); Yong-Deok TARK, Namdong-gu (KR)

(73) Assignee: HERAEUS MATERIALS TECHNOLOGY GMBH & CO. KG, Hanau (DE)

(21) Appl. No.: 14/015,119

(22) Filed: Aug. 30, 2013

(30) Foreign Application Priority Data
Sep. 4, 2012 (EP) 12 006 236.9

(51) Int. Cl. B23K 35/02; H05K 7/02

(52) U.S. Cl. CPC B23K 35/0227; H05K 7/02
USPC 361/760; 420/501; 420/502; 420/505; 148/430; 148/678; 72/286

(57) ABSTRACT

A bonding wire according to the invention contains a core having a surface, in which the core contains silver as a main component and at least one element selected from gold, palladium, platinum, rhodium, ruthenium, nickel, copper, and iridium. The wire exhibits at least one of the following properties:
I. an average size of crystal grains of the core is between 0.8 μm and 3 μm,
II. the amount of crystal grains having an orientation in the <001> direction in a wire cross section is in a range of 10-20%,
III. the amount of crystal grains having an orientation in the <111> direction in a wire cross section is in a range of 5-15%, and
IV. the total amount of crystal grains having orientations in the <001> and <111> directions in a wire cross section is in a range of 15-40%.

### BACKGROUND OF THE INVENTION

Bonding wires are used in the manufacture or fabrication of semiconductor devices for electrically interconnecting an integrated circuit and a printed circuit board. Further, bonding wires are used in power electronic applications to electrically connect transistors, diodes, and the like with pads or pins of a housing. While bonding wires were originally made from gold, less expensive materials, such as silver, are used nowadays. While silver wire provides very good electric and thermal conductivity, bonding of silver wire has its challenges.

Some recent developments have been directed to bonding wires having a core material based on silver as a main component due to its lower price compared with gold. Nevertheless, there is an ongoing need for further improving bonding wire technology with regard to the bonding wire itself and the bonding process.

### BRIEF SUMMARY OF THE INVENTION

The invention is related to a bonding wire comprising a core having a surface, in which the core comprises silver as a main component and at least one element selected from the group consisting of gold, palladium, platinum, rhodium, ruthenium, nickel, copper, and iridium.

The invention further relates to a microelectronic component package comprising a wire according to the invention and a method for manufacturing a wire according to the invention.

It is an objective of the invention to provide improved bonding wires.

Another objective of the invention is to provide a bonding wire which has good processing properties and which has no specific needs when interconnecting, thus saving costs.

It is also an objective of the invention to provide a bonding wire which has excellent electrical and thermal conductivity.

It is a further objective of the invention to provide a bonding wire which exhibits improved reliability.

A further objective of the invention is to provide a bonding wire which exhibits excellent bondability.

It is another objective of the invention to provide a bonding wire which shows improved bondability with respect to a second bonding or wedge bonding.

It is yet another objective of the invention to provide a bonding wire having a high stitch pull value as well as a low standard deviation of the stitch pull value.

It is yet a further objective of the invention to provide a bonding wire having a high ball shear value as well as a low standard deviation of the ball shear value.

It is yet a further objective of the invention to provide a bonding wire having low electrical resistivity.

It is another objective to provide a microelectronic component package, which package provides a cost effective and reliable connection between an electronic device and a substrate of the package.

It is a further objective to provide a method for manufacturing an inventive bonding wire, which method requires essentially no increase in manufacturing costs compared with known methods.

Surprisingly, wires of the present invention have been found to solve at least one of the objectives mentioned above. Further, a process for manufacturing these wires has been found which overcomes at least one of the challenges of manufacturing wires. Additionally, systems comprising the wires of the invention have been found to be more reliable at the interface between the wire and other electrical elements.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a scan of a cross section of an inventive wire, in which crystal grain borders are visible;

FIG. 2 is a graph of grain size evaluation of inventive and comparative wires;

FIG. 3 depicts an inventive wire with crystal grains of different orientation marked and evaluated;

FIG. 4 is a graph of the grain sizes of an inventive wire; and

FIG. 5 is a graph comparing the resistivities of an inventive wire and comparative wires.

### DETAILED DESCRIPTION OF THE INVENTION

A first embodiment of the invention relates to a bonding wire comprising a core having a surface, in which the core comprises silver as a main component and at least one element selected from the group consisting of gold, palladium, platinum, rhodium, ruthenium, nickel, copper and iridium. The bonding wire exhibits at least one of the following properties:

i) an average size of crystal grains of the core is between 0.8 μm and 3 μm,

ii) the amount of crystal grains having an orientation in the <001> direction in a cross section of the wire is in a range of 10-20%,

iii) the amount of crystal grains having an orientation in the <111> direction in a cross section of the wire is in a range of 5-15%, and

iv) the total amount of crystal grains having an orientation in the <001> direction and of crystal grains having an orientation in the <111> direction in a cross section of the wire is in a range of 15-40%.

For the purposes of this disclosure, the term “bonding wire” may be understood to encompass all cross-sectional shapes and all typical wire diameters, although bonding wires with circular cross-sections and thin diameters are preferred.

All contents or amounts of components are given as weight amounts. In particular, component amounts given in percent may be understood to mean weight %, and component amounts given in ppm (parts per million) may be understood to mean weight ppm. For percentage values relating to crystal grains of a specific size and/or orientation, the values refer to relative amounts of a total number of particles.

For the determination of grain sizes and/or grain orientations, wire samples were prepared, measured, and evaluated by use of electron microscopy, in particular by EBSD (Electron Backscatter Diffraction).

Preferably, the wire according to the invention has no coating layer covering the surface of the core. This provides for simple and cost saving manufacturing of the wire. However, it is not outside the scope of the invention that for specific applications, there may be a coating layer provided on the surface of the core of an inventive wire.

A component is a “main component” if the amount of this component exceeds all further components of a referenced material. Preferably, a main component comprises at least 50% of the total weight of the material.

In a preferred embodiment, the core comprises silver as a main component and at least one element selected from the group consisting of gold, palladium, and platinum.

In a preferred embodiment, the core comprises 80-95 wt. % silver, 5-12 wt. % gold, 1.5-5 wt. % palladium and up to 0.01 wt. % unavoidable impurities. In this embodiment, the amount of gold content is more preferably in the range of 6% to 10%. The amount of palladium is more preferably in the range of 2% to 5% and most preferably in the range of 2% to 4%.

In an alternative embodiment, the core comprises 90-99.7 wt. % silver, 0.3-10 wt. % gold and up to 0.01 wt. % unavoidable impurities.

In another alternative embodiment, the core comprises 90-99.7 wt. % silver, 0.3-10 wt. % palladium and up to 0.01 wt. % unavoidable impurities.

In yet another alternative embodiment, the core comprises 80-99 wt. % silver, 0-10 wt. % gold, 1-20 wt. % palladium and up to 0.01 wt. % unavoidable impurities.

In a particularly preferred embodiment of the invention, the average size of crystal grains of the core is between 1.0 μm and 1.6 μm. Such crystal grain size is particularly homogenous and contributes to good reproducibility of the wire properties.

In a most advantageous embodiment, a standard deviation of the size of the crystal grains is between 0 μm and 0.5 μm. More preferably, the standard deviation of the crystal grain size is between 0 μm and 0.4 μm, or even between 0 μm and 0.25 μm. Surprisingly, the quality and reproducibility of the wire properties are significantly enhanced if the crystal grains are particularly homogenous in size.

Generally, the grain size and further structure of the grains, such as their orientation, may be adjusted by appropriate selection of known manufacturing parameters. These include annealing parameters, such as annealing temperature and exposure time, as well as other parameters, such as the number of pulling steps, respective diameter reduction, etc.

In a most preferred embodiment of the invention, the wire is exposed to an intermediate annealing step prior to a final pulling step of the wire. The term “intermediate annealing” refers to annealing that is performed before further steps or measures influencing the microstructure of the wire are taken, such as pulling of the wire.

Exposure of the wire to an annealing step prior to using the wire in a bonding process may be generally understood to include such an intermediate annealing step or, alternatively, a final annealing step. Such a final annealing step may be understood to be a last step in wire production influencing the wire microstructure. Parameters of such final annealing steps are well known in the art.

When exposing the wire to a final annealing step, it is most preferred if an intermediate annealing step has been previously performed, so that at least two different annealing procedures are performed in the production of the wire. Operations which influence the microstructure of the wire, such as pulling steps, may be performed between the intermediate annealing and the final annealing. This allows for a particular optimization of the crystal structure of an inventive wire.

The inventive wires may be produced from core precursors, which refer to any pre-form of the final wire core and which may be produced by production steps such as rolling, pulling, heating, etc. In a preferred embodiment, a core precursor has a diameter of at least 0.5 mm when exposed to the intermediate annealing step. Even more preferably, the diameter of the core precursor is at least 1 mm. On the other hand, the diameter of the core during intermediate annealing should not exceed 10 mm, more preferably 5 mm. When forming bonding wires, in particular thin bonding wires, from such core precursors by pulling or other forming methods, performing intermediate annealing prior to the forming steps significantly helps to obtain an advantageous crystal structure.

It is generally preferred if the diameter reduction ratio obtained by forming steps, in particular pulling steps, between the final wire diameter and the intermediately annealed core is in a range of 0.1 to 0.002, more preferably from 0.05 to 0.005.

It is within the scope of the invention for further optimization of the wire to comprise several intermediate annealing procedures. However, for efficiency of production, only one intermediate annealing step is preferred.

In a preferred embodiment of the invention, the intermediate annealing step comprises exposing the wire to an annealing temperature of at least 350° C. for an exposure time of at least 5 minutes. A more preferred annealing temperature is in a range of 400° C. to 600° C., and most preferably between 450° C. and 550° C. The intermediate annealing time is more preferably longer than 30 minutes, most preferably in the range of 30 minutes to 120 minutes.

A particularly preferred embodiment of the invention combines the more preferred annealing temperatures with the more preferred exposure times of the intermediate annealing. In this embodiment, an annealing temperature between 450° C. and 550° C. is combined with an exposure time of between 30 minutes and 120 minutes.

In yet a further embodiment of the invention, the wire is exposed to a cooling step of at least five minutes after exposure to the annealing temperature during the intermediate annealing.

A cooling step may be understood to refer to a downward sloping temperature curve from the annealing temperature to a lower temperature. This lower temperature may be room temperature or any other temperature at which no more significant changes in the structure of the wire occurs. In particular, the lower temperature may be a normal operational temperature of the wire, as such operational temperatures are chosen in a range where no significant influence on the crystal structure is expected. An example for a typical operational temperature e.g., for usual LED applications, is about 70° C.

The shape of a temperature vs. time diagram from the start to the end of the cooling step is preferably, but not necessarily, linear.

A specifically advantageous influence on the crystal structure is achieved if the duration of the cooling step is at least half of the duration of the exposure time of the intermediate annealing. Even more preferably, the duration of the cooling step is about the same as the duration of the intermediate annealing step. Surprisingly, a rather slow and controlled cooling significantly improves the homogeneity of the crystal structure.

The present invention is particularly related to thin bonding wires. The observed effects are specifically beneficial to thin wires, in particular concerning control of grain size and grain orientation. For the purposes of this disclosure, the term “thin wire” describes a wire having a diameter in the range of 8 μm to 80 μm. More preferably, a thin wire according to the invention has a diameter of less than 30 μm. In such thin wires, the inventive composition and annealing steps particularly help to achieve beneficial properties.

Such thin wires typically, but not necessarily, have a cross-sectional view essentially in the shape of a circle. The term “cross-sectional view” in the present context refers to a view of a cut through the wire, wherein the plane of the cut is perpendicular to the longitudinal extension of the wire. The cross-sectional view may be found at any position on the longitudinal extension of the wire. A “longest path” through the wire in a cross-section is the longest chord which may be laid through the cross-section of the wire within the plane of the cross-sectional view. A “shortest path” through the wire in a cross-section is the longest chord perpendicular to the longest path within the plane of the cross-sectional view defined above. If the wire has a perfect circular cross-section, then the longest path and the shortest path become indistinguishable and share the same value. The term “diameter” is the arithmetic mean of all geometric diameters of any plane and in any direction, wherein all planes are perpendicular to the longitudinal extension of the wire.

The invention also relates to a microelectronic component package comprising an electronic device and a substrate which are connected to each other by a bonding wire according to the invention. In a preferred embodiment of the component package, the electronic device is a light emitting diode. It has been found that the wire according to the invention is not only excellently suitable for bonding such LED devices, but also the reflectivity of the wire material gives good results for this particular application.

The invention further relates to a method for manufacturing a bonding wire according to the invention, comprising the steps of

a. providing a wire core precursor;

b. pulling the precursor until a final diameter of the wire core is reached; and

c. annealing the pulled wire at a minimum annealing temperature for a minimum annealing time.

The wire core precursor may be understood to have the same composition as the bonding wire. Such a precursor may be simply obtained by melting a defined amount of silver, adding the further components in the defined amounts, and forming a homogenous mixture. The wire core precursor may then be cast or formed in any known manner from the molten or solidified alloy. It may be understood that the pulling of the precursor in step b may be performed in several steps.

In a most preferred embodiment of the invention, the method further comprises a step of:

d. intermediate annealing of the wire core precursor prior to step b.

This additional intermediate annealing step results in optimization of the crystal structure prior to the strong mechanical deformations which occur when pulling the wire or the like. It has been found that the intermediate annealing is beneficial for the final microstructure of the wire. For instance, intermediate annealing may help to reduce the deviation of grain size in the final product, may improve the orientation of the grains, and more. The parameters of the intermediate annealing may be adapted with respect to the required wire parameters but preferably, the minimum intermediate annealing temperature is 350° C. and the minimum intermediate annealing time is 5 minutes.

Advantageously, the method further comprises a step of cooling the wire for at least five minutes after intermediate annealing from at least the annealing temperature down to not more than a usual operational temperature. Other preferred details of the method for manufacturing the wire, in particular with respect to optimized annealing parameters, may be understood by considering the above description of the bonding wire according to the invention.

The invention may be further understood with reference to the following, non-limiting examples.

### Wire Preparation

An alloy was prepared by melting a predetermined amount of pure silver and adding predetermined amounts of pure gold and palladium in order to obtain a well-mixed composition as follows (in weight-%): Silver-Gold-Palladium 89%-8%-3%.

The molten mixture was cast into a form and cooled to obtain a wire core precursor having a diameter of 2 mm. The 2 mm diameter wire core precursor was then annealed in an intermediate annealing step. In this step, the core precursor was inserted into an annealing oven preheated to a temperature of 500° C. The core precursor remained in the oven at a constant temperature of 500° C. for an exposure time of 90 minutes.

The intermediate annealing step was continuously followed by a cooling step with the following parameters: decreasing the oven temperature linearly from 500° C. down to room temperature during a time period of 90 minutes.

The intermediately annealed core precursor was then pulled to a thin wire of 18 μm final diameter in several pulling steps. Finally, the resulting 18 μm wire was annealed in a final annealing step with usual annealing parameters. The resulting wire according to the invention was used for several tests.

### Wire Analysis

First, the inventive wire was compared with two comparative (standard) wires based on silver alloys similar to the inventive wire. The comparison measurements include the resistivity of the wires, stitch pull behavior, and ball shearing behavior. To determine these properties of the wires, standard tests procedures in the field of wire bonding were used.

FIG. 5 is a graph comparing the resistivities of the three wires. The inventive wire according to the invention is W1, and the two comparative wires are C1 and C2. The resistivity values of the wires are shown in Table 1.

TABLE 1
Resistivity

| | W1 | C1 | C2 |
|---|---|---|---|
| Resistivity [μΩ × cm] | 4.66 | 4.80 | 5.10 |

It can be seen that the inventive wire sample W1 has the lowest resistivity by far (less than 4.7 μΩ×cm), which generally is a very advantageous feature of a bonding wire.

Considering stitch pull behavior, advantageous features include not only high stitch pull values, but even more so low deviations of the values because a low deviation provides for high control and reliability in a manufacturing process.

The stitch pull results for the three wires are summarized in Table 2 below:

TABLE 2
Stitch Pull Properties

| Stitch pull [grams] | W1 | C1 | C2 |
|---|---|---|---|
| Minimum | 2.0 | 2.2 | 2.0 |
| Maximum | 2.8 | 3.9 | 2.6 |
| Average | 2.4 | 2.9 | 2.2 |
| Stand. deviation σ | 0.2 | 0.5 | 0.2 |

The data show that inventive wire W1 has advantages relative to comparative wire C1 because it is has a significantly lower deviation. Further, the inventive wire is at least as advantageous as comparative wire C2 because it has a higher average stitch pull value with the same deviation.

Considering ball shear property, advantageous features include not only high pull values, but even more so low deviations of the values because a low deviation provides for high control and reliability in a manufacturing process. The ball shear results for the three wires are summarized in Table 3 below:

TABLE 3
Ball Shear Properties

| Ball shear [grams] | W1 | C1 | C2 |
|---|---|---|---|
| Minimum | 11.1 | 10.6 | 10.6 |
| Maximum | 14.5 | 13.6 | 13.2 |
| Average | 12.6 | 12.0 | 12.0 |
| Stand. deviation σ | 0.2 | 0.5 | 0.2 |

The data on the ball shearing property show that the inventive wire is advantageous over both comparison wires because it has the highest average value combined with the lowest deviation.

### Further Analysis of Inventive Wire Properties

In the following, the inventive wire is described in detail with respect to its specific properties. An inventive wire as described above was prepared for analysis as follows. First, a piece of the wire was coiled onto a steel support having a rectangular cross section. Next, the coiled wire and steel support were embedded in a resin by molding and a cross section through the embedded wire was cut. The cross sectional area of the wire was then polished in several steps with a final polishing grain size of 0.04 μm. Finally, the polished surface was cleaned and then treated by ion milling.

Several measurements were made on the microtexture of the wire, in particular by means of Electron Backscattering Diffractometry (EBSD) using a FE-SEM Hitachi S-4300E. The software package used for measurement and data evaluation is called TSL and is commercially available from Edax Inc., US (www.edax.com).

Based on these measurements, size and distribution of the crystal grains of the wire, as well as the crystal orientation, were determined. It may be understood that a tolerance angle of 5° was set for the determination of grain boundaries when performing the measurement and evaluation of crystal grains by EBSD measurement,

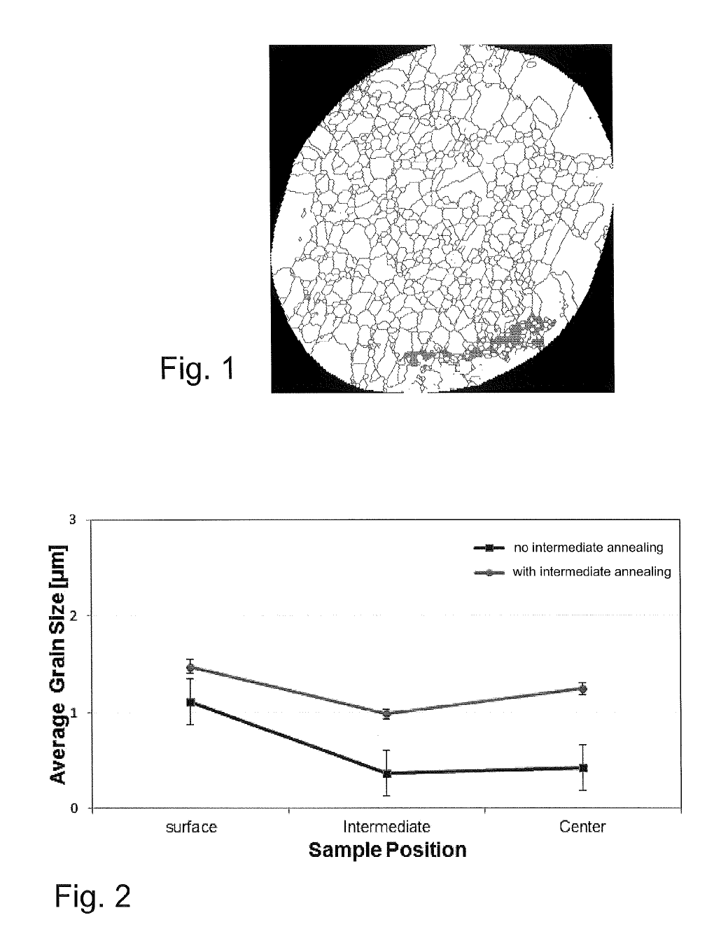

FIG. 1 shows a scan of an 18 μm diameter cross section through the inventive wire, in which the crystal grains of the wire material are indicated by their grain boundaries. All of the single crystal grains have been evaluated with respect to their size and their crystal orientation.

In this evaluation, three different regions of the cross section have been defined for a better in-depth understanding. These regions are named “surface,” “intermediate,” and “center,” based on a radial distance from the center of the essentially circular cross section. Each of the three regions has about the same share of the total cross sectional area.

FIG. 2 is a graph of average size of the crystal grains for each wire region for a wire produced without an intermediate annealing and cooling step (lower curve) and for a wire produced by a method in which intermediate annealing and cooling steps having been performed, as described above (upper curve). The standard deviation of the size of the grains is displayed by perpendicular bars at the respective diagram point.

The total average grain size is about 1.2 μm for the intermediately annealed wire, with a standard deviation of less than 0.13 μm averaged over the different regions. For the different regions, no average grain size was below 1 μm and no standard deviation was greater than 0.15 μm.

An orientation was set with reference to the lengthwise direction of the wire samples and defined as the <001> orientation.

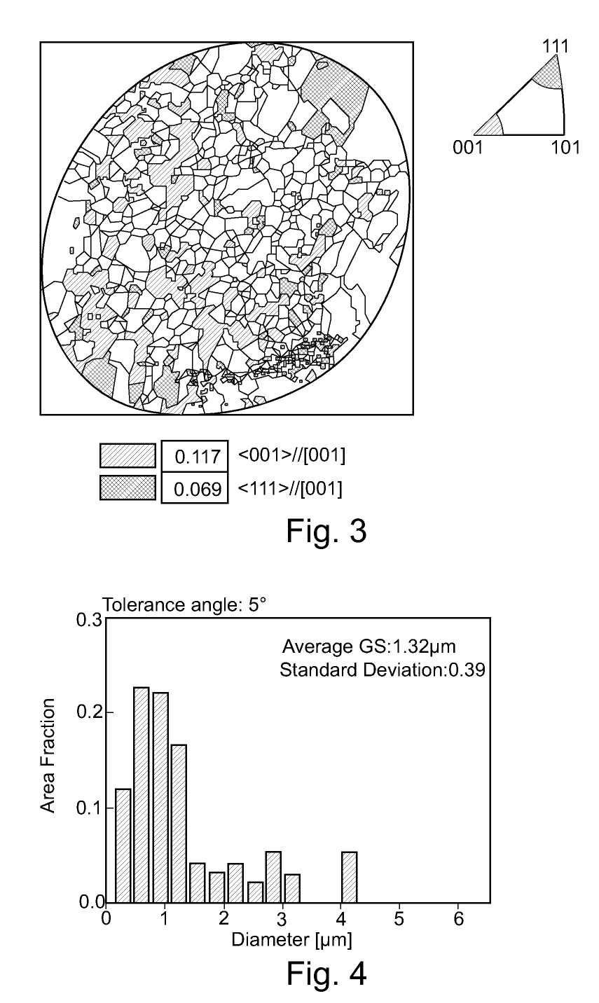

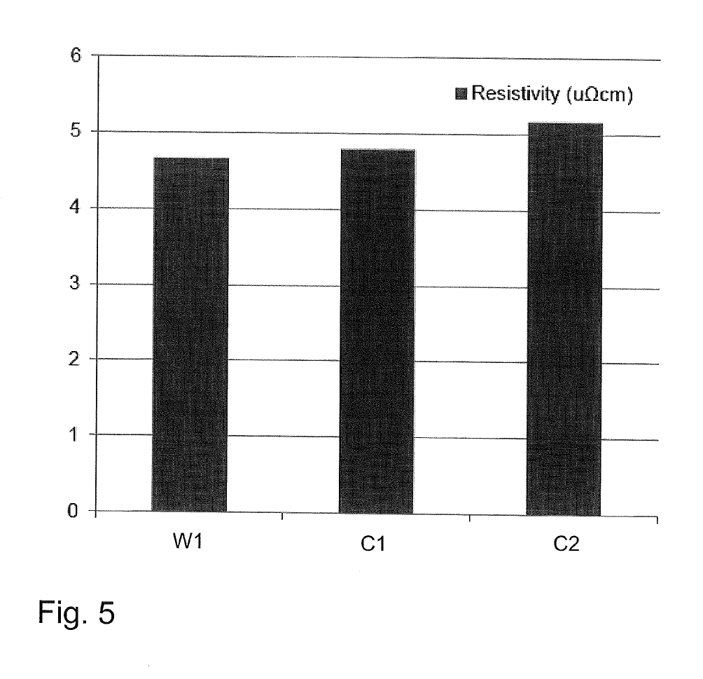

As shown in FIG. 3, the crystal grains of the wire of FIG. 1 were evaluated for their orientation with respect to the wire axis. In the top right corner of FIG. 3, a triangle references the different orientations as a commonly used way of presentation. The three basic or main orientations <001>, <101>, and <111> belong to the respective corners of the triangle.

For the present evaluation, a crystal grain is defined to belong to the <001> orientation (or <111> orientation, respectively), if its measured orientation is within a tolerance angle of 15° with respect to the <001> orientation (or <111> orientation, respectively). In the triangle, these tolerance angles are visible for the case of the <001> orientation and the <111> orientation as filled areas, with two different shades of grey for the two orientations. The respective grains of these orientations are marked in the same color of grey shade in the wire cross section. The other grains of white color do not belong to the <001> or the <111> orientation.

Evaluation of the counted grains shows that 11.7% of the total number of grains belong to the <001> orientation and 6.9% of the total number of grains belong to the <111> orientation.

A comparison with the comparative wires C1 and C2 is shown in Table 4.

TABLE 4
Crystal Grain Properties

| Number share of grains [%], tolerance 15° | W1 | C1 | C2 |
|---|---|---|---|
| <001> orientation | 11.7 | 8.2 | 27.0 |
| <111> orientation | 6.9 | 3.4 | 20.3 |
| sum of <001> and <111> orientation | 18.6 | 11.6 | 47.3 |

These results and further evaluation confirm that the inventive wire samples have a distribution of particles of specific orientations with the following properties:

a. The amount of crystal grains having an orientation in the <001> direction in the cross section of the wire is in the range of 10-20%.

b. The amount of crystal grains having an orientation in the <111> direction in the cross section of the wire is in the range of 5-15%.

c. The total amount of crystal grains having an orientation in the <001> direction and of crystal grains having an orientation in the <111> direction in the cross section of the wire is in the range of 15-40%.

d. An average size of crystal grains of the core is between 0.8 μm and 3 μm.

It has been found that inventive wires having at least one of these properties exhibit good properties in the bonding processes, as described above. Further advantageously, any two or more of the features a-d are simultaneously present.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A bonding wire comprising a core having a surface, wherein the core comprises silver as a main component and at least one element selected from the group consisting of gold, palladium, platinum, rhodium, ruthenium, nickel, copper and iridium, wherein the bonding wire exhibits at least one of the following properties:
an average size of crystal grains of the core is between 0.8 μm and 3 μm,
an amount of crystal grains having an orientation in a <001> direction in a cross section of the wire is in a range of 10-20%,
an amount of crystal grains having an orientation in a <111> direction in a cross section of the wire is in a range of 5-15%, and
a total amount of crystal grains having an orientation in the <001> direction and of crystal grains having an orientation in the <111> direction in a cross section of the wire is in a range of 15-40%.

2. The bonding wire according to claim 1, wherein the core comprises silver as a main component and at least one element selected from the group consisting of gold, palladium, and platinum.

3. The bonding wire according to claim 1, wherein the core comprises 80-95 wt. % silver, 5-12 wt. % gold, 1.5-5 wt. % palladium and up to 0.01 wt. % unavoidable impurities.

4. The bonding wire according to claim 1, wherein the core comprises 90-99.7 wt. % silver, 0.3-10 wt. % gold and up to 0.01 wt. % unavoidable impurities.

5. The bonding wire according to claim 1, wherein the core comprises 90-99.7 wt. % silver, 0.3-10 wt. % palladium and up to 0.01 wt. % unavoidable impurities.

6. The bonding wire according to claim 1, wherein the core comprises 80-99 wt. % silver, 0-10 wt. % gold, 1-20 wt. % palladium and up to 0.01 wt. % unavoidable impurities.

7. The bonding wire according to claim 1, wherein the average size of crystal grains of the core is between 1.0 μm and 1.6 μm.

8. The bonding wire according to claim 1, wherein a standard deviation of the size of the crystal grains is between 0 μm and 0.5 μm.

9. The bonding wire according to claim 1, wherein a standard deviation of the size of the crystal grains is between 0 μm and 0.4 μm.

10. The bonding wire according to claim 1, wherein the wire is formed by exposing a core precursor to an intermediate annealing step prior to a final pulling step.

11. The bonding wire according to claim 10, wherein the core precursor has a diameter of at least 0.5 mm when exposed to the intermediate annealing step.

12. The bonding wire according to claim 10, wherein the intermediate annealing step comprises exposing the wire to an annealing temperature of at least 350° C. for an exposure time of at least 5 minutes.

13. The bonding wire according to claim 10, wherein the wire is exposed to a cooling step after the intermediate annealing step, and wherein a duration of the cooling step is at least 5 minutes.

14. The bonding wire according to claim 13, wherein a duration of the cooling step is at least half of a duration of the intermediate annealing step.

15. The bonding wire according to claim 10, wherein a diameter of the wire is in a range of 10-30 μm.

16. A microelectronic component package comprising an electronic device and a substrate, wherein the electronic device and the substrate are connected to each other by a bonding wire according to claim 1.

17. A method for manufacturing a bonding wire according to claim 1, comprising the steps of:
a. providing a wire core precursor;
b. pulling the precursor to reach a final diameter of the wire core; and
c. annealing the pulled wire at a minimum annealing temperature for a minimum annealing time.

18. The method according to claim 17, further comprising a step of
d. intermediate annealing of the wire core precursor prior to step b.

19. The method according to claim 18, wherein a minimum intermediate annealing temperature is 350° C. and a minimum intermediate annealing time is 5 minutes.

20. The method according to claim 18, further comprising a step of
e. cooling the wire after intermediate annealing from at least an intermediate annealing temperature down to not more than a usual operational temperature, wherein the cooling has a duration of at least 5 minutes.
